(19) United States
(12) Patent Application Publication
(10) Pub. No.: US 2013/0147463 A1
(43) Pub. Date: Jun. 13, 2013

(54) CURRENT SENSOR AND ASSEMBLED BATTERY

(71) Applicants: Shinichi Takase, Yokkaichi-shi (JP); Yuko Kinoshita, Yokkaichi-shi (JP); Kensaku Takata, Yokkaichi-shi (JP); Hiroki Hirai, Yokkaichi-shi (JP); Takashi Misaki, Yokkaichi-shi (JP); Kouji Nishi, Yokkaichi-shi (JP)

(72) Inventors: Shinichi Takase, Yokkaichi-shi (JP); Yuko Kinoshita, Yokkaichi-shi (JP); Kensaku Takata, Yokkaichi-shi (JP); Hiroki Hirai, Yokkaichi-shi (JP); Takashi Misaki, Yokkaichi-shi (JP); Kouji Nishi, Yokkaichi-shi (JP)

(73) Assignees: AUTONETWORKS TECHNOLOGIES, LTD., Yokkaichi-shi, Mie (JP); SUMITOMO ELECTRIC INDUSTRIES, LTD., Osaka-shi, Osaka (JP); SUMITOMO WIRING SYSTEMS, LTD., Yokkaichi-shi, Mie (JP)

(21) Appl. No.: 13/818,423

(22) PCT Filed: Aug. 25, 2011
(86) PCT No.: PCT/JP2011/069123

§ 371 Date: Feb. 22, 2013

(30) Foreign Application Priority Data
Aug. 27, 2010 (JP) 2010-190496

(51) Int. Cl. G01R 19/00

(52) U.S. Cl. CPC G01R 19/0092
USPC 324/117 R

(57) ABSTRACT

There are provided a deformed bus bar for electrically connecting terminals of adjacent battery cells in an assembled battery, a core having both ends opposed to each other across a clearance and continuously formed around a hollow portion through which a part of the deformed bus bar penetrates, and a Hall IC disposed in the clearance for outputting an electric signal depending on a magnetic flux.

### TECHNICAL FIELD

The present invention relates to a technique for detecting a current in an electric circuit using an assembled battery as a power supply.

### BACKGROUND ART

In a hybrid car, an electric car, or the like, a current sensor for detecting a current in an electric circuit is provided in order to detect a disorder or a failure which has occurred in the circuit. With a conventional general structure, a current sensor is disposed in a connection box (a so-called junction block) collecting control circuits of various electrical components and the like in a car (for example, see Patent Document 1).

### PRIOR ART DOCUMENT

### Patent Document

Patent Document 1: Japanese Patent Application Laid-Open No. 2006-230163

### SUMMARY OF INVENTION

### Problems to be Solved by the Invention

In recent years, a reduction in size of a junction block is desired in view of space saving in a vehicle. However, an occupation space for a current sensor in the junction block disturbs the reduction in size of the junction block.

In view of the above problem, an object of the present invention is to provide a technique capable of implementing the reduction in size of the junction block.

### Means for Solving the Problem

A current sensor according to a first aspect includes a conductor for electrically connecting terminals of adjacent battery cells in an assembled battery, a magnetic material core having both ends opposed to each other across a clearance and continuously formed around a hollow portion through which a part of the conductor penetrates, and a magneto-electric converting element disposed in the clearance for outputting an electric signal depending on a magnetic flux.

A current sensor according to a second aspect is the current sensor according to the first aspect, wherein the conductor is formed by extending from one of the two adjacent terminals toward the other and the conductor includes an erected portion formed in a direction crossing a terminal formation surface which is a surface on which the terminal is provided in the battery cell in a middle thereof, and the erected portion penetrates through the hollow portion of the magnetic material core.

A current sensor according to a third aspect is the current sensor according to the second aspect, wherein the conductor includes two erected portions, and a bridge portion laid between the two erected portions for connecting the erected portions, and one of the two erected portions penetrates through the hollow portion of the magnetic material core.

A current sensor according to a fourth aspect is the current sensor according to the third aspect, wherein the magneto-electric converting element is disposed between the bridge portion and the terminal formation surface.

A current sensor according to a fifth aspect is the current sensor according to the first aspect, wherein the conductor includes two terminal corresponding portions making contact with the two adjacent terminals respectively, two first extended portions formed by extending in a second direction orthogonal to a first direction which is an array direction of the two terminal corresponding portions from the two terminal corresponding portions respectively, and a second extended portion which extends by connecting ends of the two first extended portions, and a part of the second extended portion penetrates through the hollow portion of the magnetic material core.

A current sensor according to a sixth aspect is the current sensor according to the fifth aspect, wherein the conductor includes an erected portion formed in a middle of the second extended portion in a direction crossing a terminal formation surface which is a surface on which the terminal is formed in the battery cell, and the erected portion penetrates through the hollow portion of the magnetic material core.

A current sensor according to a seventh aspect is the current sensor according to any of the first to sixth aspects, and includes an accommodating case for holding and accommodating the conductor, the magnetic material core, and the magneto-electric converting element in a certain positional relationship while electrically insulating them.

An assembled battery according to an eighth aspect includes a plurality of battery cells arranged in a line, a plurality of conductors for electrically connecting terminals of mutually adjacent ones of the plurality of battery cells, a magnetic material core having both ends opposed to each other across a clearance and continuously formed around a hollow portion through which a part of one of the plurality of conductors penetrates, and a magneto-electric converting element disposed in the clearance for outputting an electric signal depending on a magnetic flux.

An assembled battery according to a ninth aspect is the assembled battery according to the eighth aspect, and includes an accommodating case for accommodating the plurality of conductors respectively, and a coupling structure for coupling the adjacent accommodating cases, wherein any of the accommodating cases which accommodates the conductor penetrating through the hollow portion of the magnetic material core holds and accommodates the conductor, the magnetic material core, and the magneto-electric converting element in a certain positional relationship while electrically insulating them.

### Effects of the Invention

According to the first to ninth aspects, the current sensor is disposed on the terminal formation surface of the assembled battery (a surface on which the terminal in each of the battery cells constituting the assembled battery is formed) by setting, as a detecting target, the conductor for electrically connecting the terminals of the adjacent battery cells in the assembled battery. Accordingly, it is not necessary to dispose the current sensor in a junction block and a reduction in size of the junction block can be realized.

Particularly, according to the second and third aspects, since the magnetic material core surrounds the erected portion formed in the direction crossing the terminal formation surface, it is possible to control a size of the current sensor in a normal direction of the terminal formation surface.

Particularly, according to the fourth aspect, since the magneto-electric converting element is disposed in a space formed between the conductor and the terminal formation surface, the current sensor can be made compact. Accordingly, it is possible to effectively utilize a space on the terminal formation surface without having the current sensor wastefully occupying the space conforming to the terminal formation surface.

Particularly, according to the fifth aspect, since the first extended portions respectively extending from the two terminal corresponding portions are provided in the direction orthogonal to the array direction of the terminal corresponding portion, it is possible to minimize a size of the conductor in the array direction of the terminal corresponding portion. Accordingly, it is possible to effectively utilize the space on the terminal formation surface without having the current sensor wastefully occupying the terminal formation surface.

Particularly, according to the sixth aspect, since the magnetic material core surrounds the erected portion formed in the middle of the second extended portion which extends by connecting the ends of the first extended portions, it is possible to prevent the magnetic material core from protruding toward the outside of the first extended portion in the array direction of the terminal corresponding portion (or to reduce a protrusion width). Accordingly, it is possible to prevent the current sensor from protruding to the adjacent battery cell (or to reduce the protrusion width) by decreasing the width of the current sensor (a width in the array direction of the terminal corresponding portion).

Particularly, according to the seventh aspect, the conductor, the magnetic material core, and the magneto-electric converting element can be insulated electrically, and furthermore, can be held in a proper positional relationship.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing a current sensor attached to an assembled battery, in which a case is not illustrated.

FIG. 2 is a perspective view showing a deformed bus bar.

FIG. 3 is an enlarged view showing the current sensor attached to the assembled battery.

FIG. 4 is a plan view showing the current sensor attached to the assembled battery.

FIG. 5 is a view showing the current sensor attached to the assembled battery.

FIG. 6 is a perspective view showing a standard case and a standard bus bar accommodated therein.

FIG. 7 is a perspective view showing the deformed case, the deformed bus bar accommodated therein, a core, and a Hall IC.

### EMBODIMENT FOR CARRYING OUT THE INVENTION

<1. Assembled Battery 2>

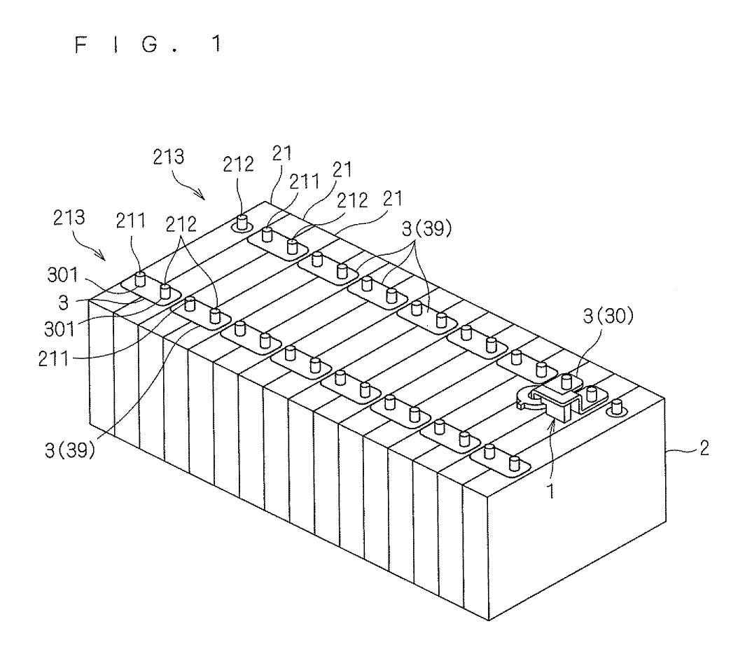

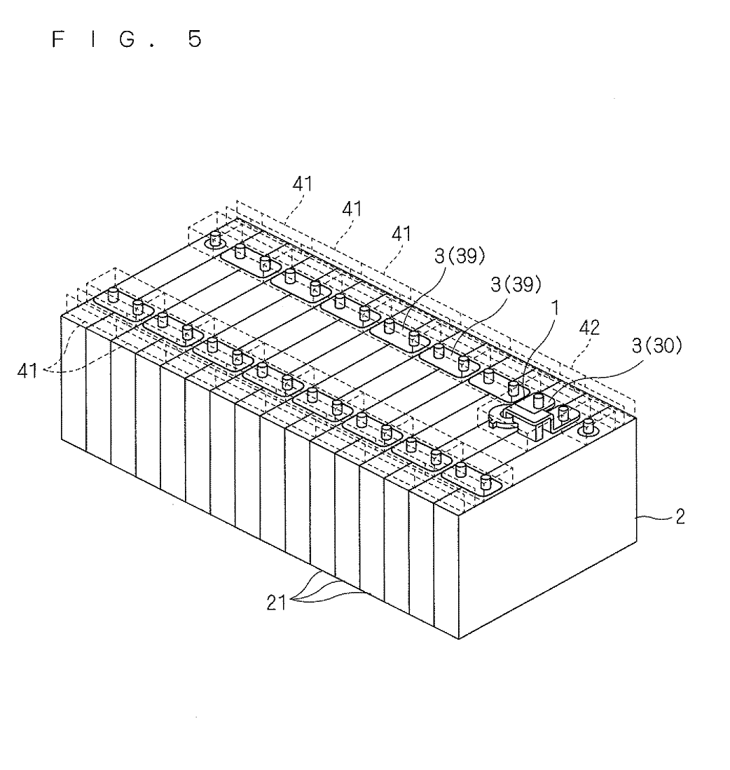

A current sensor 1 according to an embodiment of the present invention is attached to an assembled battery 2. Before specific explanation of the current sensor 1, the assembled battery 2 having the current sensor 1 attached thereto will be described with reference to FIG. 1. FIG. 1 shows the assembled battery 2 and a plurality of bus bars 3 to be attached thereto. Although the plurality of bus bars 3 are actually attached to the assembled battery 2 in an accommodating state in a case (see FIG. 5), the case is not illustrated in FIG. 1 for simplicity of the drawing.

The assembled battery 2 has a plurality of battery cells 21 arranged therein, and the plurality of battery cells 21 are electrically connected in series through the bus bar 3. By such an assembled battery 2, a high output voltage can be obtained. The assembled battery 2 is often employed in various devices requiring a comparatively high output voltage, for example, a hybrid car, an electric car, and the like.

A structure of the assembled battery 2 will be described more specifically. The assembled battery 2 includes the plurality of battery cells 21 arranged in a predetermined direction. The plurality of battery cells 21 are arranged with terminal formation surfaces (surface on which a pair of terminals (a positive terminal 211 and a negative terminal 212) is formed) facing upward. Moreover, the plurality of battery cells 21 are superposed and arranged with directions of the positive terminals 211 and the negative terminals 212 alternate to each other, respectively. Accordingly, the positive terminal 211 and the negative terminal 212 are alternately arranged in each of two terminal lines 213 formed in an array direction of the plurality of battery cells 21.

In the terminal line 213, the adjacent pairs of positive terminal 211 and negative terminal 212 are electrically connected through the bus bar 3. Consequently, the plurality of battery cells 21 are electrically connected in series. The bus bar 3 is a conductor for electrically connecting the terminals 211 and 212 of the adjacent battery cells 21. More specifically, the bus bar 3 is a plate-shaped member formed by an electrically conductive material; and a terminal corresponding portion making contact with the positive terminal 211 or the negative terminal 212 of the battery cell 21 is formed on each of both ends thereof. In the present embodiment, the terminals 211 and 212 of the battery cell 21 have a tubular shape, and a circular through hole 301 for inserting the positive terminal 211 or the negative terminal 212 having the tubular shape is formed on each terminal corresponding portion.

The positive terminal 211 and the negative terminal 212 which are adjacent to each other in the terminal line 213 are respectively inserted into the through holes 301 formed on the both ends of the bus bar 3, and are fixed by means of a nut member or the like so that the adjacent positive terminal 211 and negative terminal 212 are electrically connected to each other. It should be noted that a terminal not forming a pair is present on one of the ends of the terminal line 213 (both ends in the case where an odd number of battery cells 21 are provided). A bus bar having one through hole formed thereon or a round terminal fixture is attached to the terminal.

<2. Current Sensor 1>

<2-1. Deformed Bus Bar 30>

In the current sensor 1 according to the embodiment of the present invention, one of the bus bars 3 to be attached to the assembled battery 2 is set to be a detecting target. The bus bar 3 to be the detecting target in the current sensor 1 has a special shape, and this bus bar 3 is hereinafter referred to as a “deformed bus bar 30”. Moreover, the bus bar 3 other than the deformed bus bar 30 is referred to as a “standard bus bar 39”.

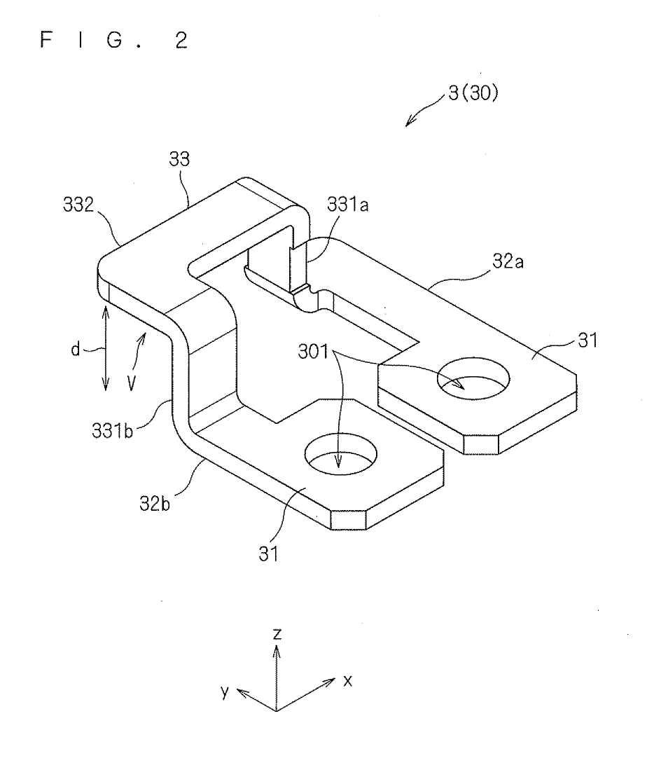

The deformed bus bar 30 will be described with reference to FIG. 2. FIG. 2 is a perspective view showing the deformed bus bar 30.

The deformed bus bar 30 which is a kind of the bus bar 3 functions as a connecting member for connecting a pair of the terminals (the adjacent positive terminal 211 and negative terminal 212 in the terminal line 213) in optional positions in the terminal line 213 formed on the assembled battery 2 as described above. In other words, a terminal corresponding portion 31 making contact with a terminal acting as a connecting target (the adjacent positive terminal 211 or negative terminal 212 in the terminal line 213) is formed on each of both ends of the deformed bus bar 30. The terminal corresponding portion 31 is formed to have a wide plate shape, and the through hole 301 for inserting the terminal acting as the connecting target is formed on a central part thereof. A lower surface of each terminal corresponding portion 31 is positioned on the same plane, and the plane is hereinafter referred to as a “reference surface”. The deformed bus bar 30 is attached to the assembled battery 2 in such a posture that the reference surface is parallel with the terminal formation surface.

The deformed bus bar 30 includes two first extended portions 32a and 32b which are formed by extending in an orthogonal direction (a Y direction) to an array direction (an X direction) of two terminal corresponding portions 31 from the two terminal corresponding portions 31, and a second extended portion 33 which extends by connecting ends of the two first extended portions 32a and 32b.

The first extended portion 32 is formed to have a smaller width than the terminal corresponding portion 31. Accordingly, a constricted part (hereinafter simply referred to as a “constriction part”) is formed between the terminal corresponding portion 31 and the first extended portion 32.

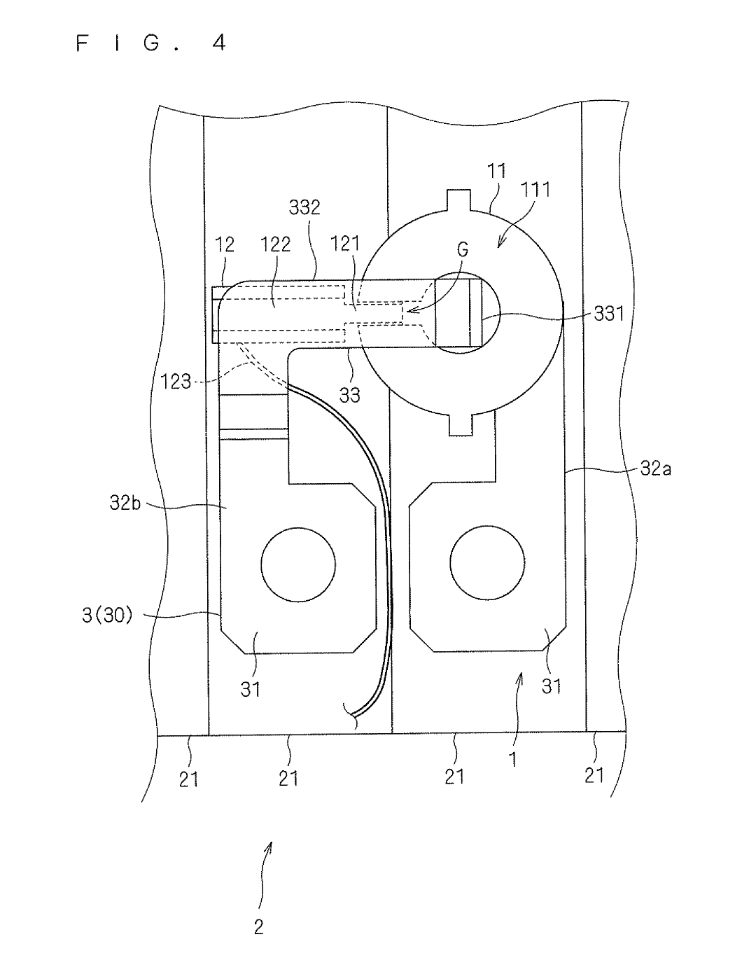

The first extended portions 32a and 32b are plate-shaped and are extended along the reference surface from the terminal corresponding portion 31. In other words, the first extended portions 32a and 32b are extended in the Y direction along the reference surface and a termination portion is also positioned on the reference surface. Moreover, the termination portion of the first extended portion (the first extended portion on a +X side in FIG. 4) 32a is bent in a −X-axis direction.

The second extended portion 33 includes two erected portions 331a and 331b which are formed in a middle thereof and which erect and extend in a direction crossing the reference surface (a normal direction of the reference surface (a Z direction) in an example of FIG. 4). In the two erected portions 331a and 331b, the erected portion 331a is connected to the end of the first extended portion 32a, that is, an end having a tip bent in the −X direction, and is formed in a position between the two terminal corresponding portions 31 with respect to the array direction (the X direction) of the terminal corresponding portion 31. Moreover, the other erected portion 331b is connected to the end of the other first extended portion 32b, that is, an end placed in the same position as the terminal corresponding portion 31 with respect to the X direction, and is formed in the same position as one of the terminal corresponding portions 31 with respect to the X direction.

Moreover, the second extended portion 33 includes a bridge portion 332 laid over the two erected portions 331a and 331b and connecting them. The bridge portion 332 is extended in a position placed apart from the reference surface by a certain distance (hereinafter, referred to as a “distance d”). In other words, a space V is formed between the bridge portion and the reference surface.

<2-2. Structure of Current Sensor 1>

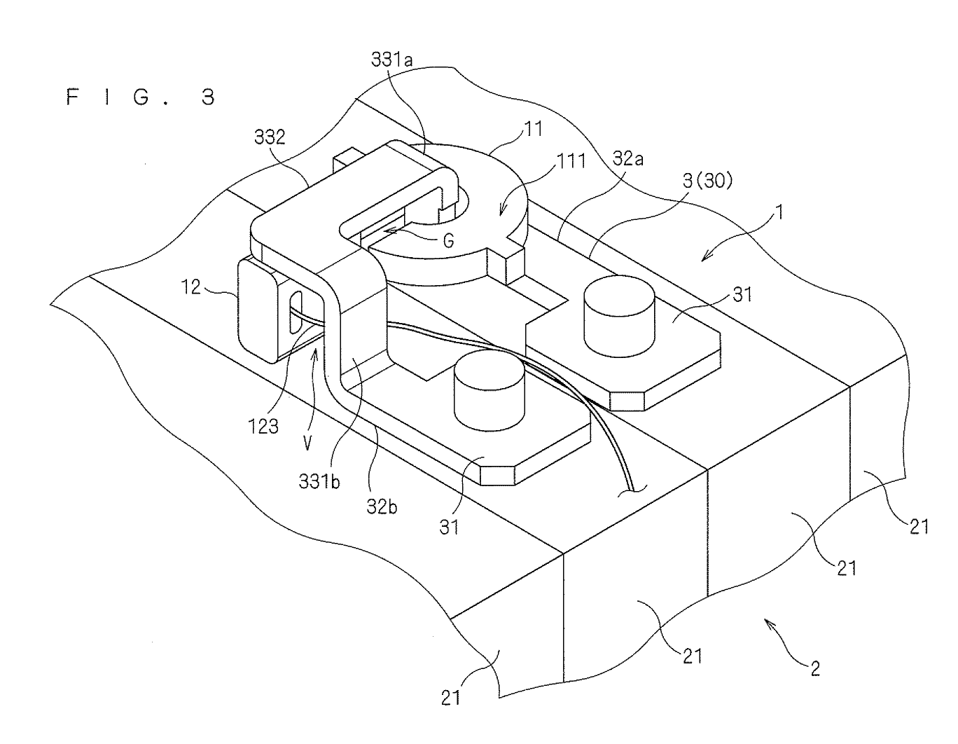

A structure of the current sensor 1 will be specifically described with reference to FIGS. 3 and 4. FIG. 3 is an enlarged view showing the current sensor 1 attached to the assembled battery 2. FIG. 4 is a plan view showing the current sensor 1 illustrated in FIG. 3.

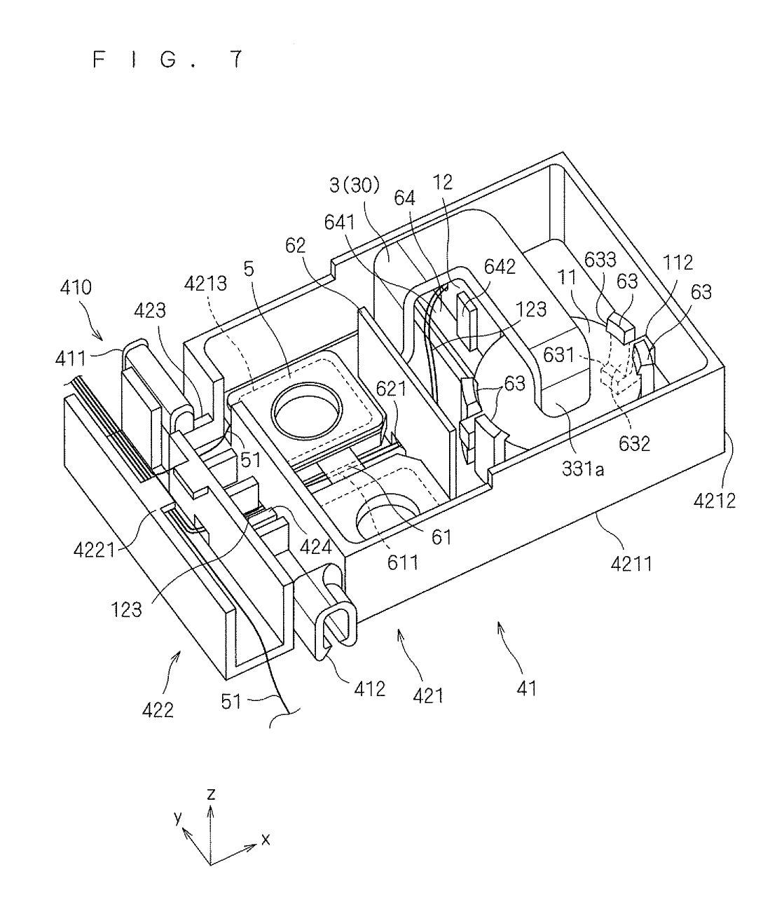

The current sensor 1 includes the deformed bus bar 30 described above, a core 11 constituted by a magnetic body, and a Hall IC 12. The current sensor 1 further includes a deformed case 42 for accommodating these components 30, 11, and 12. The components 30, 11, and 12 provided in the current sensor 1 are actually attached to the assembled battery 2 in an accommodating state in the deformed case 42 (See FIG. 7. The deformed case 42 is not illustrated in FIGS. 3 and 4 for simplicity of the drawings.). The deformed case 42 will be described later.

The core 11 is formed to have a shape which is bent around a detecting target (a conductor through which a current to be detected flows, that is, the deformed bus bar 30) and a clearance G is thus provided between both ends (in the present embodiment, a C shape in plan view). More specifically, the core 11 has both ends opposed to each other across the clearance G and is continuously formed around a hollow portion through which a part of the deformed bus bar 30 penetrates. The core 11 converges a magnetic flux generated by a flow of a current to the detecting target.

The Hall IC 12 is a magnetic sensor in which a magneto-electric converting element (which is assumed to be a Hall element, for example, in the present embodiment) 121 for converting a magnetic flux into an electric signal and an amplifier circuit 122 for amplifying the electric signal output from the Hall element 121 are integrated, and outputs an electric signal corresponding to the magnetic flux. The Hall element 121 is disposed in the clearance G of the core 11, and converts the magnetic flux converged by the core 11 into an electric signal and outputs the electric signal.

A lead wire 123 extends from the Hall IC 12. An end of the lead wire 123 is electrically connected to a control portion (not shown), and the electric signal output from the Hall IC 12 is transmitted to the control portion through the lead wire 123.

When a current flows to the deformed bus bar 30 which is the detecting target, the magnetic flux proportional to a quantity of the current is converged by the core 11 and penetrates through the Hall element 121 disposed in the clearance G. The Hall element 121 converts the magnetic flux into an electric signal and outputs the electric signal. The electric signal output from the Hall element 121 is amplified by the amplifier circuit 122 and is output to the control portion through the lead wire 123.

<2-3. Positional Relationship>

Description will be given to a positional relationship of the core 11 and the Hall IC 12 with respect to the deformed bus bar 30.

The core 11 is disposed in such a posture that the erected portion 331a of the deformed bus bar 30 (the erected portion 331a formed in a position between the two terminal corresponding portions 31 with respect to the array direction (the X direction) of the two terminal corresponding portions 31 in the two erected portions 331a and 331b formed in the deformed bus bar 30) penetrates through the hollow portion formed on a center thereof. As described above, the erected portion 331a extends in a direction crossing the reference surface (that is, a direction crossing the terminal formation surface of the battery cell 21). Accordingly, the core 11 is disposed in such a posture that a main surface 111 conforms to the terminal formation surface of the battery cell 21.

Moreover, the Hall IC 12 is disposed in the space V formed between the bridge portion 332 of the deformed bus bar 30 and the reference surface. In other words, the core 11 is disposed in such a posture that the clearance G is positioned below the bridge portion 332, and the Hall element 121 is disposed in the clearance G of the core 11 which is positioned below the bridge portion 332.

<3. Case>

The structures of the standard bus bar 39 and the current sensor 1 which are attached to the assembled battery 2 have been described above. However, the standard bus bar 39 and the components (the deformed bus bar 30, the core 11, and the Hall IC 12) provided in the current sensor 1 are actually attached to the assembled battery 2 in an accommodating state in cases 41 and 42 as shown in FIG. 5. In other words, the standard bus bar 39 is attached to the assembled battery 2 in the accommodating state in the standard case 41. Moreover, the deformed bus bar 30, the core 11, and the Hall IC 12 provided in the current sensor 1 are attached to the assembled battery 2 in the accommodating state in the deformed case 42 (that is, as assembled parts in which the respective structures 30, 11, and 12 are accommodated in the deformed case 42). The structures of the respective cases 41 and 42 will be specifically described.

<3-1. Standard Case 41>

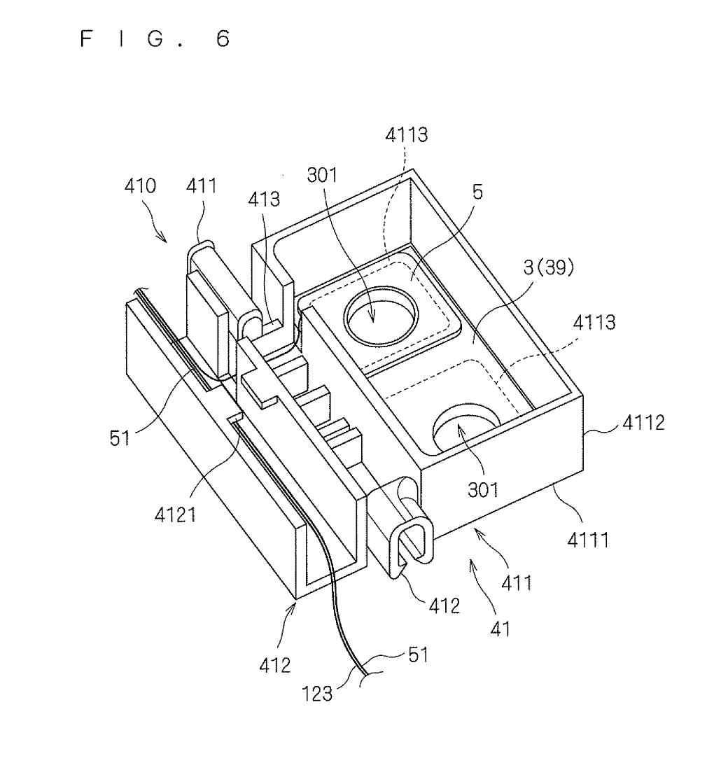

The structure of the standard case 41 will be described with reference to FIG. 6. FIG. 6 is a perspective view showing the standard case 41 and the standard bus bar 39 accommodated therein.

The standard case 41 includes an accommodating portion 411 for accommodating one standard bus bar 39 and a voltage detecting fixture 5, and a conducting wire accommodating piece 412 for accommodating various kinds of conducting wires (a conducting wire 51 extending from the voltage detecting fixture 5 and the lead wire 123 extending from the current sensor 1). The voltage detecting fixture 5 is a terminal which is provided on an end of the conducting wire 51 connected to a voltage monitoring circuit (not shown) and which electrically connects the conducting wire 51 to a terminal of an electrode cell. Although not illustrated, the standard case 41 is actually attached to the assembled battery 2 with a cover put thereon.

The accommodating portion 411 includes a bottom portion 4111 forming a support surface for supporting the standard bus bar 39 and having a rectangular shape in plan view, and a peripheral wall 4112 erected around the bottom portion 4111. The peripheral wall 4112 functions as an insulating wall for preventing the standard bus bar 39 assembled into the assembled battery 2 from making contact with the adjacent bus bar 3.

On the bottom portion 4111, there is formed a window 4113 which is an opening for inserting the terminals 211 and 212 of the battery cell 21 into the through hole 301 of the standard bus bar 39 accommodated in the accommodating portion 411.

The conducting wire accommodating piece 412 is a chute-shaped member for accommodating various kinds of conducting wires 51 and 123. The conducting wire accommodating piece 412 may be provided with a conducting wire pressing claw 4121, which bundles the conducting wires 51 and 123 to be accommodated therein.

The conducting wire accommodating piece 412 is connected to the accommodating portion 411 through a guide path 413. In a connecting portion to the guide path 413, an opening is formed on the peripheral wall 4112 of the accommodating portion 411. Moreover, an opening is also formed on a wall surface of the conducting wire accommodating piece 412 in the connecting portion to the guide path 413. The conducting wire 51 extending from the voltage detecting fixture 5 to be accommodated in the accommodating portion 411 is led to the conducting wire accommodating piece 412 through the opening formed on the peripheral wall 4112 of the accommodating portion 411, the guide path 413, and the opening formed on the wall surface of the conducting wire accommodating piece 412.

The conducting wire 51 led to the conducting wire accommodating piece 412 is successively guided to the conducting wire accommodating piece 412 of the adjacent standard case 41 (or a conducting wire accommodating piece 422 of the deformed case 42), and is thus led to the control portion. In other words, as shown in FIG. 5, the plurality of standard cases 41 and the deformed case 42 are arranged in a line so that the plurality of conducting wire accommodating pieces 412 and 422 are arranged in a line over the terminal formation surface of the assembled battery 2, whereby a single conducting wire accommodating path is formed. The conducting wire 51 extending from the voltage detecting fixture 5 accommodated in each of the cases 41 and the lead wire 123 extending from the Hall IC 12 accommodated in the deformed case 42 are led to the control portion through the conducting wire accommodating path (see FIG. 5).

<3-2. Deformed Case 42>

A structure of the deformed case 42 will be described with reference to FIG. 7. FIG. 7 is a perspective view showing the deformed case 42, and the deformed bus bar 30, the core 11, and the Hall IC 12 which are accommodated therein.

In FIG. 7, there is appended an XYZ coordinate system in which an X axis conforms to a depth direction of the deformed case 42 (a direction of an array of the deformed accommodating portion 421 and the conducting wire accommodating piece 422) and a Y axis conforms to a width direction of the deformed case 42 (a direction of an array of two windows 4213).

The deformed case 42 includes the deformed accommodating portion 421 for accommodating the deformed bus bar 30, the core 11, the Hall IC 12, and the voltage detecting fixture 5, and the conducting wire accommodating piece 422 for accommodating various kinds of conducting wires (the conducting wire 51 extending from the voltage detecting fixture 5 and the lead wire 123 extending from the current sensor 1). Although not illustrated, the deformed case 42 is actually attached to the assembled battery 2 with a cover put thereon.

The deformed accommodating portion 421 includes a bottom portion 4211 which forms a support surface for supporting the deformed bus bar 30 and the current sensor 1 and has a rectangular shape in plan view, and a peripheral wall 4212 which is erected around the bottom portion 4211. The peripheral wall 4212 functions as an insulating wall for preventing the deformed bus bar 30 and the current sensor 1 assembled into the assembled battery 2 from making contact with the adjacent bus bar 3.

Moreover, on the bottom portion 4211, there is formed a window 4213 which is an opening for inserting the terminals 211 and 212 of the battery cell 21 into the through hole 301 of the deformed bus bar 30 accommodated in the deformed accommodating portion 421.

On the deformed accommodating portion 421, an insulating member is erected which holds the respective members accommodated in the deformed accommodating portion 421 in a certain positional relationship while insulating the members from each other. Specifically, a first insulating wall 61, a second insulating wall 62, a core supporting portion 63, and a Hall IC supporting portion 64 are erected as the insulating members.

The first insulating wall 61 is erected between the two windows 4213 (that is, a position corresponding to a portion between the two terminal corresponding portions 31 provided in the standard bus bar 39 accommodated in the deformed accommodating portion 421), and functions as an insulating wall for insulating the respective terminal corresponding portions 31 from each other.

A thickness of the first insulating wall 61 is designed to be substantially equal to or slightly smaller than a distance between the terminal corresponding portions 31, and the deformed bus bar 30 accommodated in the deformed accommodating portion 421 is fixed with respect to the width direction (the Y direction) of the deformed accommodating portion 421 by fitting the first insulating wall 61 between the two terminal corresponding portions 31 provided therein. In other words, the first insulating wall 61 also has a function of a positioning member for defining a position of the deformed bus bar 30 with respect to the width direction (the Y direction) of the deformed accommodating portion 421.

The second insulating wall 62 is erected in a posture along the Y direction at the +X direction side of the first insulating wall 61. The second insulating wall 62 is erected in a position corresponding to a portion between the terminal corresponding portion 31 of the standard bus bar 39 accommodated in the deformed accommodating portion 421 and the core 11 and functions as an insulating wall for insulating the terminal corresponding portion 31 and the core 11.

It is particularly preferable that the second insulating wall 62 be erected in a position corresponding to a constriction part of the standard bus bar 39 accommodated in the deformed accommodating portion 421 (a constricted part between the terminal corresponding portion 31 and the first extended portions 32a and 32b). In this case, the deformed bus bar 30 accommodated in the deformed accommodating portion 421 is fixed with respect to the width direction (the Y direction) and the depth direction (the X direction) of the deformed accommodating portion 421 by abutment of the second insulating wall 62 on the constriction part. In other words, in this case, the second insulating wall 62 also has a function of a positioning member for defining the position of the deformed bus bar 30 with respect to the width direction (the Y direction) and the depth direction (the X direction) of the deformed accommodating portion 421.

A plurality of core supporting portions 63 (four in FIG. 7) are erected in positions corresponding to a region where the core 11 is accommodated in the deformed accommodating portion 421 (a region on an opposite side to a region in which the first insulating wall 61 is formed with respect to the second insulating wall 62) along a side of the core 11. More specifically, the core supporting portion 63 includes a base 631 for supporting a bottom surface of the core 11, a neck portion 632 extending from the base 631 and having a circular arc shape in plan view, and a claw portion 633 which is formed on an upper end of the neck portion 632 and is to be caught on an upper surface of the core 11.

The core 11 accommodated in the deformed case 42 is mounted on the base 631 of each core supporting portion 63, and furthermore, the claw portion 633 of each core supporting portion 63 is caught on the upper surface. Consequently, the core 11 is fixed into a position higher than a bottom surface of the deformed accommodating portion 421 with respect to the height direction (the Z direction) of the deformed accommodating portion 421. Thus, the core 11 is supported in a middle of the erected portion 331 of the second extended portion 33 in the deformed case 42 while avoiding contact with the deformed bus bar 30.

Moreover, the core 11 accommodated in the deformed accommodating portion 421 is fixed with respect to the width direction (the Y direction) and the depth direction (the X direction) of the deformed accommodating portion 421 while avoiding the contact with the deformed bus bar 30 by abutment of the neck portion 632 of each core supporting portion 63 on a side surface thereof.

Two protruded portions 112 protruded in a circumferential direction are formed on the core 11, and the core supporting portion 63 abuts on both sides of each of the protruded portions 112 in an accommodating state in the deformed accommodating portion 421. Consequently, the core 11 is also fixed in a rotating direction.

The Hall IC supporting portion 64 is erected in a position corresponding to a region where the Hall IC 12 is accommodated in the deformed accommodating portion 421 (a region on an opposite side to the region where the first insulating wall 61 is formed with respect to the second insulating wall 62). The Hall IC supporting portion 64 specifically includes a base 641 for supporting a bottom surface of the Hall IC 12, and a side wall 642 for defining a position by abutting on a side surface of the Hall IC 12. It is also possible to further provide a claw portion which is formed on an upper end of the side wall 642 and is to be caught on the upper surface of the Hall IC 12.

The Hall IC 12 accommodated in the deformed case 42 is mounted on the base 631 of the Hall IC supporting portion 64, and furthermore, is fixed into a position higher than a bottom surface of the deformed accommodating portion 421 by abutment of the side surface 642 on a side surface thereof. Consequently, the Hall IC 12 is fixed to the space V provided below a specific extended portion in the deformed case 42.

An opening 621 for conducting the lead wire 123 is formed below the second insulating wall 62. Moreover, an opening 611 for conducting the lead wire 123 is also formed below the first insulating wall 61. As will be described below, furthermore, an opening for conducting the lead wire 123 is also formed below the peripheral wall 4212 of the accommodating portion 421. The lead wire 123 extending from the Hall IC 12 is led to the below-described conducting wire accommodating piece 422 through the opening 621 formed on the second insulating wall 62, the opening 611 formed on the first insulating wall 61, and the opening formed on the peripheral wall 4212 in this order.

Subsequently, description will be given to the conducting wire accommodating piece 422 to be connected to the conducting wire accommodating piece 422. The conducting wire accommodating piece 422 is a chute-shaped member for accommodating various kinds of conducting wires 51 and 123. It is also possible to form, on the conducting wire accommodating piece 422, a conducting wire pressing claw 4221 for bundling the conducting wires 51 and 123 to be accommodated therein.

The conducting wire accommodating piece 422 is connected to the deformed accommodating portion 421 through two guide paths (a first guide path 423 and a second guide path 424). In a connecting portion to each of the guide paths 423 and 424, an opening is formed on the peripheral wall 4212 of the deformed accommodating portion 421. Moreover, in a connecting portion to each of the guide paths 423 and 424, an opening is also formed on the wall surface of the conducting wire accommodating piece 422. The conducting wire 51 extending from the voltage detecting fixture 5 accommodated in the accommodating portion 421 is led to the guiding wire accommodating piece 422 through the opening formed on the peripheral wall 4212 of the accommodating portion 421, the first guide path 423, and the opening formed on the wall surface of the conducting wire accommodating piece 422. On the other hand, the lead wire 123 extending from the current sensor 1 accommodated in the accommodating portion 421 is led to the guiding wire accommodating piece 422 through the opening formed on the peripheral wall 4212 of the accommodating portion 421, the second guide path 424, and the opening formed on the wall surface of the conducting wire accommodating piece 422.

The conducting wires 51 and 123 led to the conducting wire accommodating piece 412 are successively led to the conducting wire accommodating piece 412 of the adjacent standard case 41 and are thus guided to the control portion (see FIG. 5).

<3-3. Coupling Structure 410>

The respective standard cases 41 and the deformed case 42 are arranged in a line, and the adjacent cases are coupled to each other through a coupling structure 410.

As shown in FIGS. 6 and 7, for example, the coupling structure 410 is formed by a coupling bar 411 which is provided on one of ends in the width direction of the cases 41 and 42, and a fitting portion 412 which is provided on the other end in the width direction and is to be fitted in the coupling bar 411. The coupling bar 411 of the standard case 41 (or deformed case 42) adjacent to the cases 41 and 42 is fitted in the fitting portion 412 of the standard case 41 (or the deformed case 42) so that the adjacent cases 41 and 42 are coupled to each other.

By coupling and integrally forming the plurality of standard cases 41 accommodating the standard bus bar 39 and the deformed case 42 accommodating the deformed bus bar 30 and the current sensor 1, it is possible to attach the plurality of bus bars 3 and the current sensor 1 to the terminal line 213 by attachment of the coupling member to the terminal line 213 formed in the assembled battery 2. In other words, by previously coupling the cases 41 and 42, it is possible to considerably improve operating efficiency of an operation for attaching the bus bar 3 and the current sensor 1.

It is particularly preferable that the coupling structure 410 be slidable in a coupling direction. In the case of the coupling structure 410 according to the example described above, it is possible to provide a slide width corresponding to a length of the coupling bar 411 by regulating the length. By setting the coupling structure 410 to be a slidable structure in the coupling direction, it is possible to absorb a variation occurring in an array pitch of the terminal in the terminal line 213 (a variation caused by a dimensional tolerance, a thermal expansion or thermal contraction of the battery cell 21, or the like) if any.

<4. Effect>

According to the above embodiment, the current sensor 1 is disposed on the terminal formation surface of the assembled battery 2 by setting, as a detecting target, the deformed bus bar 30 for electrically connecting the terminals 211 and 212 of the battery cells 21 which are adjacent to each other in the assembled battery 2. Accordingly, it is not necessary to dispose the current sensor 1 in a junction block, and a reduction in size of the junction block can be realized.

Moreover, according to the above embodiment, the core 11 surrounds the erected portion 331a formed in the direction crossing the terminal formation surface. Therefore, it is possible to control the size of the current sensor 1 in the normal direction of the terminal formation surface.

Moreover, according to the above embodiment, the Hall IC 12 is disposed in the space V formed between the deformed bus bar 30 and the terminal formation surface. Therefore, the current sensor 1 can be made compact. Accordingly, it is possible to effectively utilize a space on the terminal formation surface without having the current sensor 1 wastefully occupying the space V conforming to the terminal formation surface.

Moreover, according to the above embodiment, the first extended portions 32a and 32b respectively extending from the two terminal corresponding portions 31 are provided in the orthogonal direction (the Y direction in FIG. 2) to the array direction of the terminal corresponding portion 31 (the X direction in FIG. 2). Therefore, it is possible to minimize a size of the deformed bus bar 30 in the array direction of the terminal corresponding portion 31. Accordingly, it is possible to effectively utilize the space on the terminal formation surface without having the deformed bus bar 30 wastefully occupying the terminal formation surface.

Moreover, according to the above embodiment, the core 11 surrounds the erected portion 331a formed in the middle of the second extended portion 33 which extends by connecting the ends of the first extended portions 32a and 32b (particularly, the erected portion 331a formed in a position between two first extended portions 32a in the array direction of two terminal corresponding portions 31). Therefore, it is possible to prevent the core 11 from protruding toward the outside of the first extended portions 32a and 32b in the array direction of the terminal corresponding portion 31 (or to reduce a protrusion width). Accordingly, it is possible to prevent the current sensor 1 from protruding to the adjacent battery cell 21 (or to reduce the protrusion width) by decreasing the width of the current sensor 1 (a width in the array direction of the terminal corresponding portion 31).

Moreover, according to the above embodiment, by providing the deformed case 42 for accommodating the deformed bus bar 30, the core 11, and the Hall IC 12, it is possible to electrically insulate the respective portions 30, 11, and 12, and furthermore, to hold the respective portions 30, 11, and 12 in a proper positional relationship.

<5. Variant>

Although the core 11 is formed to have the C shape in plan view in the above embodiment, the shape of the core 1.1 is not limited thereto, and any shape may be employed as long as the core 11 is bent around the detecting target and the clearance G is formed between both ends. For example, it is also possible to have a rectangular shape in plan view in which the clearance G is formed in a part.

Moreover, the deformed bus bar 30 may not necessarily have the shape described in the above embodiment. For example, in the case where there is formed such a step that the portion having the terminal 212 erected is higher than the other portions in the terminal formation surface of the assembled battery 2, it is also possible to employ a structure in which the erected portions 331a and 331b in the deformed bus bar 30 extend to be erected from the side of the bridge portion 332 toward the sides of the first extended portions 32a and 32b, respectively.

Moreover, although the two erected portions 331a and 331b are formed in the deformed bus bar 30 in the above embodiment, the positions in which the two erected portions 331a and 331b are to be formed are not limited to those described above. For example, both of the erected portions 331a and 331b may be formed in positions between the two terminal corresponding portions 31 with respect to the array direction of the two terminal corresponding portions 31 (the X direction).

Furthermore, the positions in which the core 11 and the Hall IC 12 are to be disposed with respect to the deformed bus bar 30 may not necessarily be equivalent to those described in the above embodiment. For example, the core 11 may be disposed in such a posture that the erected portion 331b of the deformed bus bar 30 penetrates through the hollow portion on the center. In addition, the Hall IC 12 may be disposed outside the first extended portions 32a and 32b.

Moreover, in the above embodiment, the current sensor 1 may be attached to any position of the assembled battery 2. Although the attachment position of the current sensor 1 is set to be the vicinity of the end of the terminal line 213 in the example of FIG. 1, it is possible to change the attachment position into an optional position (for example, the vicinity of the center of the terminal line 213 or the like) depending on a layout of various components to be mounted on the terminal formation surface.

Furthermore, two current sensors 1 or more may be attached to a single assembled battery 2. For example, the current sensor 1 for backup may further be attached in addition to the current sensor 1 for regular use.

Moreover, a direction in which the current sensor 1 is to be attached is not restricted to that illustrated in the above embodiment. In the example of FIG. 1, although the current sensor 1 is disposed in such a posture that the deformed bus bar 30 turns the second extended portion 33 toward the central side of the assembled battery 2, it may be disposed in such a posture that the second extended portion 33 is turned toward the outside of the assembled battery 2.

While the invention has been shown and described in detail, the foregoing description is in all aspects illustrative and not restrictive. It is therefore understood that numerous modifications and variations can be devised without departing from the scope of the invention.

### DESCRIPTION OF REFERENCE SIGNS

1 current sensor

2 assembled battery

3 bus bar

11 core

12 Hall IC

30 deformed bus bar

31 terminal corresponding portion

32a, 32b first extended portion

33 second extended portion

331a, 331b erected portion

332 bridge portion

1. A current sensor comprising:
a conductor for electrically connecting terminals of adjacent battery cells in an assembled battery;
a magnetic material core having both ends opposed to each other across a clearance and continuously formed around a hollow portion through which a part of said conductor penetrates; and
a magneto-electric converting element disposed in said clearance for outputting an electric signal depending on a magnetic flux.

2. The current sensor according to claim 1, wherein
said conductor is formed by extending from one of said two adjacent terminals toward the other and said conductor includes an erected portion formed in a direction crossing a terminal formation surface which is a surface on which said terminal is provided in said battery cell in a middle thereof, and
said erected portion penetrates through the hollow portion of said magnetic material core.

3. The current sensor according to claim 2, wherein
said conductor includes:
two said erected portions; and
a bridge portion laid between said two erected portions for connecting said erected portions, and
one of said two erected portions penetrates through the hollow portion of said magnetic material core.

4. The current sensor according to claim 3, wherein said magneto-electric converting element is disposed between said bridge portion and said terminal formation surface.

5. The current sensor according to claim 1, wherein
said conductor includes:
two terminal corresponding portions making contact with said two adjacent terminals respectively;
two first extended portions formed by extending in a second direction orthogonal to a first direction which is an array direction of said two terminal corresponding portions from said two terminal corresponding portions respectively; and
a second extended portion which extends by connecting ends of said two first extended portions, and
a part of said second extended portion penetrates through the hollow portion of said magnetic material core.

6. The current sensor according to claim 5, wherein
said conductor includes an erected portion formed in a middle of said second extended portion in a direction crossing a terminal formation surface which is a surface on which said terminal is formed in said battery cell, and
said erected portion penetrates through the hollow portion of said magnetic material core.

7. The current sensor according to claim 1, further comprising
an accommodating case for holding and accommodating said conductor, said magnetic material core, and said magneto-electric converting element in a certain positional relationship while electrically insulating them.

8. An assembled battery comprising:
a plurality of battery cells arranged in a line;
a plurality of conductors for electrically connecting terminals of mutually adjacent ones of said plurality of battery cells;
a magnetic material core having both ends opposed to each other across a clearance and continuously formed around a hollow portion through which a part of one of said plurality of conductors penetrates; and
a magneto-electric converting element disposed in said clearance for outputting an electric signal depending on a magnetic flux.

9. The assembled battery according to claim 8, further comprising:
an accommodating case for accommodating said plurality of conductors respectively; and
a coupling structure for coupling said adjacent accommodating cases, wherein
any of said accommodating cases which accommodates said conductor penetrating through the hollow portion of said magnetic material core holds and accommodates said conductor, said magnetic material core, and said magneto-electric converting element in a certain positional relationship while electrically insulating them.
